(19) United States
(12) Patent Application Publication
(10) Pub. No.: US 2026/0328827 A1
(43) Pub. Date: Oct. 22, 2026

(54) NOISE REMOVAL CIRCUIT AND SENSOR

(71) Applicant: FANUC CORPORATION, Yamanashi (JP)

(72) Inventor: Yuuya TATEOKA, Yamanashi (JP)

(21) Appl. No.: 18/994,026

(22) PCT Filed: Sep. 7, 2022
(86) PCT No.: PCT/JP2022/033559

§ 371 Date: Jan. 14, 2025

(51) Int. Cl. G01R 29/26; B25J 13/08; G01L 5/00

(52) U.S. Cl. CPC G01R 29/26; G01L 5/0061; B25J 13/085

(57) ABSTRACT

This noise removal circuit that removes the effect of noise from the data output from a sensor circuit comprises: a conductor wire that surrounds an electric cable; a noise detection circuit for generating a noise detection signal indicating the presence or absence of noise in the electric cable on the basis of the electric signal generated in the conductor wire; and a data processing circuit that invalidates data output from the sensor circuit during an invalidation period that includes at least a period in which the noise detection signal indicates that noise has occurred.

### TECHNICAL FIELD

The present invention relates to a noise removal circuit and a sensor.

### BACKGROUND ART

A motor used for driving an arm of a robot is supplied with driving power by an inverter. The inverter is controlled based on a pulse width modulation (PWM) signal. A wiring line that supplies motor driving power subjected to PWM control is a source of occurrence of noise.

For example, an AE measuring device has been known that measures an AE generated from a measured object, and includes: a measurement AE sensor that detects an AE signal generated from the measured object; an external noise AE sensor that detects an external AE signal generated outside the measured object; a determination unit configured to determine whether there is external noise, based on the external AE signal detected by the external noise AE sensor; and a measurement processing unit configured to validate the AE signal in a case where the determination unit determines that there is no external noise when the AE signal is detected by the measurement AE sensor (for example, see PTL 1).

For example, a Rogowski current sensor has been known that includes a return line path that continuously connects a plurality of coils along one closed line and is provided in parallel with the closed line from a winding end of a last coil of the plurality of coils to a winding start side of a first coil, and that detects a voltage induced between a winding start side terminal of the first coil and a terminal of the return line path as a function of a current in a measured circuit inserted through the closed line, each coil constituting the plurality of coils is formed on a plane perpendicular to the closed line, a winding end of a certain coil and a winding start of a next coil of adjacent coils are connected by an outbound line path provided in parallel with the closed line, and the entire outbound line path and the return line path are disposed in proximity (for example, see PTL 2).

### PATENT LITERATURE

[PTL 1] JP 2010-71945A

[PTL 2] WO20117/014297A1

### SUMMARY OF INVENTION

### Technical Problem

Noise due to motor driving power has an adverse influence on accuracy of various sensors, control of various apparatuses, and the like. Therefore, it is extremely important to detect noise and remove an influence of the noise. For example, a torque sensor for detecting torque is provided on an arm of a robot, and noise due to motor driving power has an adverse influence on accuracy of the torque sensor. The problem to be solved by the present disclosure is to achieve a noise removal circuit that removes an influence of noise from data output from a sensor circuit, and a sensor including the noise removal circuit.

### Solution to Problem

According to one aspect of the present disclosure, a noise removal circuit configured to remove an influence of noise from data output from a sensor circuit includes: a lead wire being wired in such a way as to surround an electric cable; a noise detection circuit configured to generate a noise detection signal indicating occurrence or non-occurrence of noise in the electric cable, based on an electric signal generated in the lead wire; and a data processing circuit configured to invalidate data during an invalidation period including at least a period in which the noise detection signal indicates occurrence of noise among data output from the sensor circuit.

Further, according to one aspect of the present disclosure, a sensor includes: a sensor circuit configured to output data being a sensor detection result of a target object; the noise removal circuit described above configured to remove an influence of noise from data output from the sensor circuit; and a printed circuit board having an opening through which the electric cable passes, and on which the lead wire is wired in such a way as to surround the opening.

### Advantageous Effects of Invention

One aspect of the present disclosure can achieve a noise removal circuit configured to remove an influence of noise from data output from a sensor circuit, and a sensor including the noise removal circuit.

### BRIEF DESCRIPTION OF DRAWINGS

FIG. 1 is a diagram illustrating a noise removal circuit according to an embodiment of the present disclosure and a torque sensor including the noise removal circuit.

FIG. 2 is a diagram illustrating a robot including the torque sensor according to the embodiment of the present disclosure.

FIG. 3 is a diagram illustrating noise occurring due to motor driving power flowing through an electric cable.

FIG. 4 is a perspective view illustrating a printed circuit board in a first aspect of the torque sensor according to the embodiment of the present disclosure.

FIG. 5 is a perspective view illustrating the printed circuit board in a second aspect of the torque sensor according to the embodiment of the present disclosure.

FIG. 6 is a perspective view illustrating the printed circuit board in a third aspect of the torque sensor according to the embodiment of the present disclosure.

FIG. 7 is a circuit diagram illustrating a configuration of a noise detection circuit in the noise removal circuit according to the embodiment of the present disclosure.

FIG. 8 is a waveform diagram illustrating a function of the noise detection circuit in the noise removal circuit according to the embodiment of the present disclosure.

FIG. 9 is a waveform diagram illustrating a noise detection signal generated by the noise detection circuit in the noise removal circuit according to the embodiment of the present disclosure.

FIG. 10 is a waveform diagram (part 1) illustrating setting of a filter by the noise detection circuit in the noise removal circuit according to the embodiment of the present disclosure.

FIG. 11 is a waveform diagram (part 2) illustrating setting of the filter by the noise detection circuit in the noise removal circuit according to the embodiment of the present disclosure.

FIG. 12 is a waveform diagram illustrating a relationship between noise and data in an invalidation period in the embodiment of the present disclosure.

FIG. 13 is a waveform diagram illustrating data invalidation processing in a first aspect of a data processing circuit in the noise removal circuit according to the embodiment of the present disclosure.

FIG. 14 is a waveform diagram illustrating data invalidation processing in a second aspect of the data processing circuit in the noise removal circuit according to the embodiment of the present disclosure.

### DESCRIPTION OF EMBODIMENTS

Hereinafter, a noise removal circuit and a torque sensor according to an embodiment will be described with reference to drawings. It should be noted that a component having the same or similar function is provided with the same reference sign in the following description. Then, overlapping description of the components may be omitted. Further, “being connected” means “being electrically connected” in the following description.

### Overall Configuration of Noise Removal Circuit and Torque Sensor

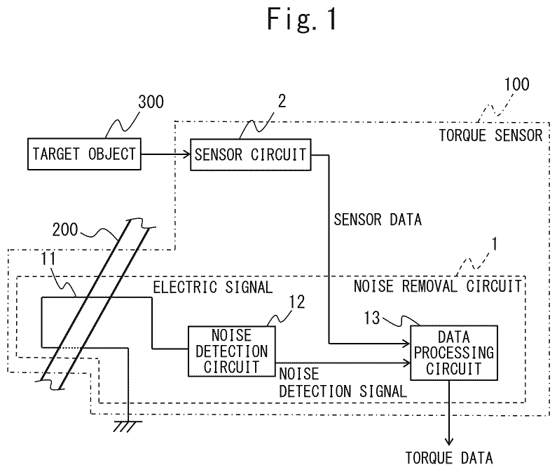

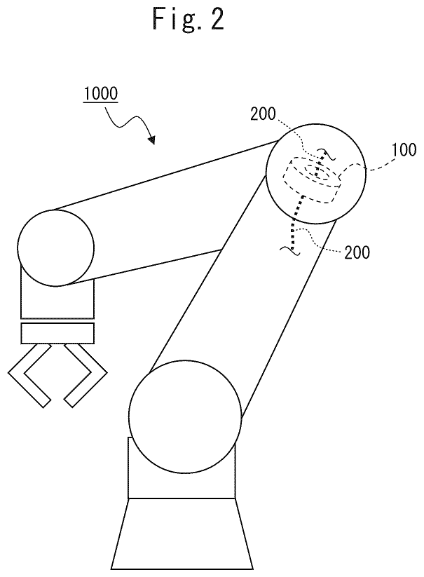

FIG. 1 is a diagram illustrating a noise removal circuit according to an embodiment of the present disclosure and a torque sensor including the noise removal circuit. FIG. 2 is a diagram illustrating a robot including the torque sensor according to the embodiment of the present disclosure.

According to the embodiment of the present disclosure, a torque sensor 100 includes a noise removal circuit 1, a sensor circuit 2, and a printed circuit board 3 (not illustrated in FIG. 1). In the present embodiment, as one example, it is assumed that the sensor circuit 2 is provided in the torque sensor 100 that detects torque of a target object 300. As a modification example, the sensor circuit 2 may be provided in a sensor other than a torque sensor. For example, the sensor circuit 2 may be a sensor circuit configured to output electrical sensor data among a current sensor, a voltage sensor, a magnetic sensor, a speed sensor, a temperature sensor, and the like.

The torque sensor 100 is provided in, for example, an arm of a robot 1000. The printed circuit board 3 of the torque sensor 100 is provided with the noise removal circuit 1, the sensor circuit 2, and the like.

The sensor circuit 2 outputs data (hereinafter referred to as “sensor data”) being a sensor detection result of the target object 300. Herein, a torque sensor is used as one example, and thus the sensor circuit 2 outputs sensor data about torque detected from the target object 300. The target object 300 being a target of torque detection is a motor that drives an arm of a robot. The sensor data output from the sensor circuit 2 may be analog data (analog signal) or may be digital data (digital signal).

The noise removal circuit 1 removes an influence of noise from the sensor data output from the sensor circuit 2. The noise removal circuit 1 includes a lead wire 11, a noise detection circuit 12, and a data processing circuit 13.

The printed circuit board 3 of the torque sensor 100 has an opening. The electric cable 200 through which motor driving power subjected to PWM control flows is disposed through the opening. The lead wire 11 is wired in such a way as to surround the opening on the printed circuit board. Thus, the lead wire 11 is wired in such a way as to surround the electric cable 200 being a source of occurrence of noise due to the motor driving power.

The noise detection circuit 12 generates a noise detection signal indicating occurrence or non-occurrence of noise in the electric cable 200, based on an electric signal generated in the lead wire 11. Details of noise detection processing by the noise detection circuit 12 will be described below.

The data processing circuit 13 invalidates the sensor data during an invalidation period including at least a period in which the noise detection signal indicates occurrence of noise among the sensor data output from the sensor circuit 2. Details of data invalidation processing by the data processing circuit 13 will be described below.

An arithmetic processing device (processor) is provided in the torque sensor 100. As the arithmetic processing device, for example, there are an IC, an LSI, a CPU, an MPU, a DSP, and the like. The data processing circuit 13 may be formed of only the arithmetic processing device, may be formed of a combination of an analog circuit and the arithmetic processing device, or may be formed of only the analog circuit. For example, when the data processing circuit 13 is constituted in a software program form, the arithmetic processing device performs a motion according to the software program, and thus a function of the data processing circuit 13 can be achieved. Alternatively, the data processing circuit 13 may be achieved as a semiconductor integrated circuit to which a software program achieving the function of the data processing circuit 13 is written. Alternatively, the data processing circuit 13 may be achieved as a recording medium to which a software program achieving the function of the data processing circuit 13 is written.

It should be noted that the lead wire 11 and the noise detection circuit 12 may be replaced with a current detection circuit in a Rogowski coil system. In this case, the current detection circuit in the Rogowski coil system is connected to the data processing circuit 13, and the electric cable 200 is also disposed through the opening of the printed circuit board provided with a

### Principle of Occurrence of Noise by Motor Driving Power

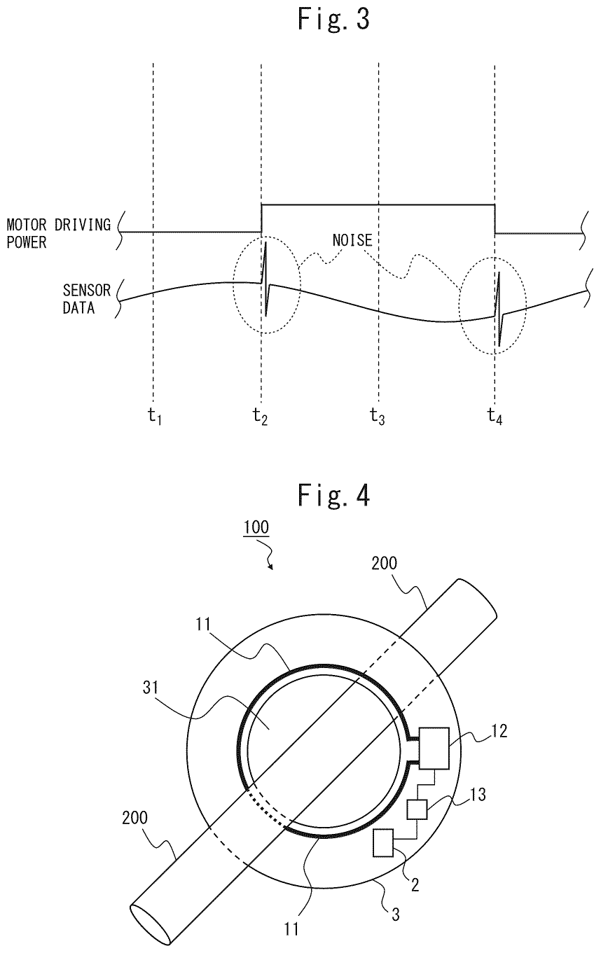

FIG. 3 is a diagram illustrating noise occurring due to the motor driving power flowing through the electric cable.

A wiring line that supplies motor driving power subjected to PWM control is a source of occurrence of noise. The motor driving power flowing through the electric cable 200 is a square wave voltage, and a minute change in a magnetic field occurs around the electric cable 200 in accordance with a change in High and Low of the square wave voltage, and noise occurs in the sensor data output from the sensor circuit 2 located near the electric cable 200. For example, as illustrated in FIG. 3, at a time t₂ at which the motor driving power is switched from Low to High and a time t₄ at which the motor driving power is switched from High to Low, a minute change in a magnetic field occurs around the electric cable 200 through which the motor driving power flows. As a result, noise occurs at the time t₂ and the time t₄ in the sensor data output from the sensor circuit 2 located near the electric cable 200.

Thus, in the embodiment of the present disclosure, the lead wire 11 is wired in such a way as to surround the electric cable 200 in order to detect a change in a magnetic field around the electric cable 200 through which the motor driving power flows. Noise in accordance with a change in the motor driving power flowing through the electric cable 200 occurs in the lead wire 11. The noise detection circuit 12 generates a noise detection signal indicating occurrence or non-occurrence of noise in the electric cable 200, based on an electric signal related to the noise occurring in the lead wire 11.

### Structure of Printed Circuit Board of Noise Removal Circuit

The printed circuit board of the torque sensor 100 provided in the arm of the robot 1000 may have an opening for passing various cables. The electric cable 200 through which the motor driving power flows is also disposed through the opening of the printed circuit board. Thus, in the embodiment of the present disclosure, the lead wire 11 is wired in such a way as to surround the opening of the printed circuit board 3 of the torque sensor 100, and thus the lead wire 11 surrounds the electric cable 200. It should be noted that, as a modification example, an opening may be provided in a housing of the torque sensor 100, the lead wire 11 may be wired in such a way as to surround the opening of the housing of the torque sensor 100, the electric cable 200 may be disposed through the opening, and thus the lead wire 11 may surround the electric cable 200.

A few aspect examples of the printed circuit board are listed below.

FIG. 4 is a perspective view illustrating the printed circuit board in a first aspect of the torque sensor according to the embodiment of the present disclosure.

The printed circuit board 3 in the first aspect has an annular shape acquired by providing an opening 31 in the vicinity of the center of a disc-shaped printed circuit board. The electric cable 200 passes through the opening 31. The lead wire 11 being wired in such a way as to surround the opening 31, the noise detection circuit 12, and the data processing circuit 13 are provided on the printed circuit board 3.

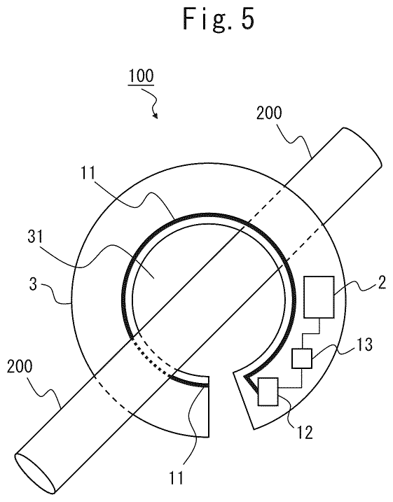

FIG. 5 is a perspective view illustrating the printed circuit board in a second aspect of the torque sensor according to the embodiment of the present disclosure.

The printed circuit board 3 in the second aspect has a shape acquired by providing the opening 31 in the vicinity of the center of a C-shaped printed circuit board having a notch in a part in a circumferential direction. The electric cable 200 passes through the opening 31. The lead wire 11 being wired in a C shape in such a way as to surround a part of the opening 31, the noise detection circuit 12, and the data processing circuit 13 are provided on the printed circuit board 3.

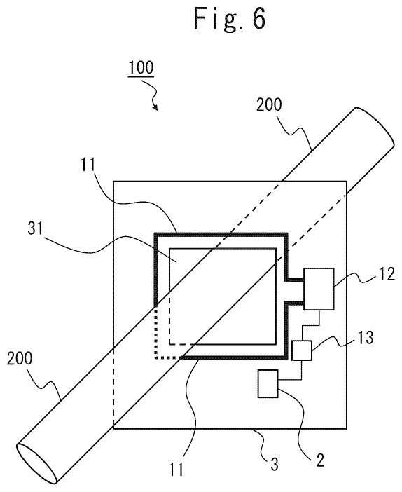

FIG. 6 is a perspective view illustrating the printed circuit board in a third aspect of the torque sensor according to the embodiment of the present disclosure.

The printed circuit board 3 in the third aspect has a shape acquired by providing the opening 31 in the vicinity of the center of a substantially quadrangular printed circuit board. The electric cable 200 passes through the opening 31. The lead wire 11 being wired in a substantially quadrangular shape in such a way as to surround the opening 31, the noise detection circuit 12, and the data processing circuit 13 are provided on the printed circuit board 3.

The first to third aspects described above are one example, and a printed circuit board shape and a wiring shape other than the illustrated shapes may be used as long as a printed circuit board in which the lead wire 11 is wired in such a way as to surround the opening 31 passed by the electric cable 200 is used.

### One Example of Configuration of Noise Detection Circuit

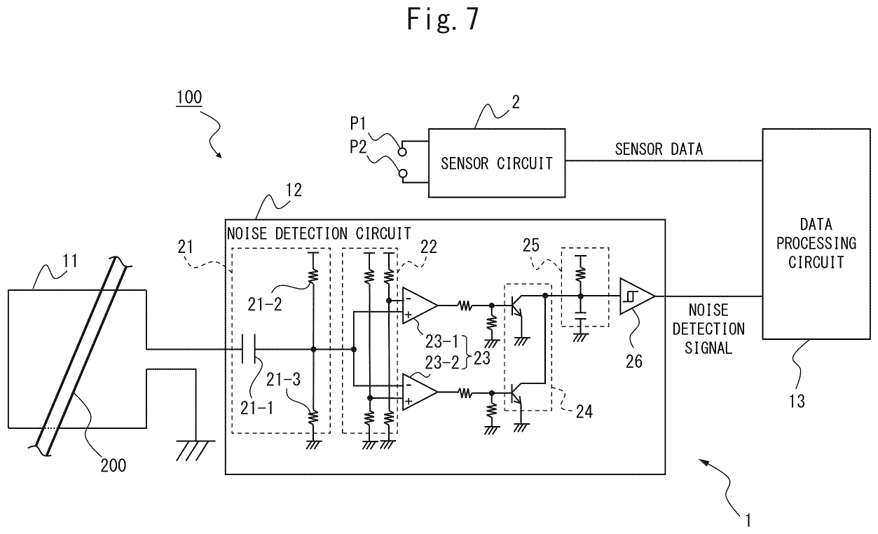

FIG. 7 is a circuit diagram illustrating a configuration of the noise detection circuit in the noise removal circuit according to the embodiment of the present disclosure.

As described above, the lead wire 11 and the data processing circuit 13 are connected to the noise detection circuit 12. A strain gauge having a resistance value changed by torque applied to a motor is connected to terminals P1 and P2 of the sensor circuit 2.

The noise detection circuit 12 includes a direct-current component adjustment unit 21, a threshold value setting unit 22, a comparison unit 23, a wired OR connection unit 24, a filter 25, and a buffer 26.

The direct-current component adjustment unit 21 includes a capacitor 21-1 configured to remove a direct-current component from an electric signal generated in the lead wire 11, and resistors 21-2 and 21-3 configured to apply a defined direct-current component. In the direct-current component adjustment unit 21, a direct-current component is removed, by the capacitor 21-1, from an electric signal generated in the lead wire 11, and a predetermined direct-current component is applied again by using the resistors 21-2 and 21-3. A voltage being reference in the case of non-occurrence of noise is adjusted by the resistors 21-2 and 21-3 in such a way as to fall between an upper threshold value and a lower threshold value (hereinafter may be referred to as a “threshold value range”) being set in the threshold value setting unit 22.

The threshold value setting unit 22, the comparison unit 23, the wired OR connection unit 24, the filter 25, and the buffer 26 constitute a noise detection signal generation unit.

The threshold value setting unit 22 is provided for setting a threshold value for detecting noise from an electric signal generated in the lead wire 11. The noise included in the electric signal generated in the lead wire 11 is a vibrational signal having a positive amplitude and a negative amplitude. In order to detect the noise, an upper threshold value used for comparison with a positive amplitude of the electric signal and a lower threshold value used for comparison with a negative amplitude of the electric signal are set by the threshold value setting unit 22. The upper threshold value is input to an inversion input (−) of a first comparator 23-1 constituting the comparison unit 23. The lower threshold value is input to a non-inversion input (+) of a second comparator 23-2 constituting the comparison unit 23.

The comparison unit 23 compares a threshold value formed of the upper threshold value and the lower threshold value with an electric signal having a direct-current component adjusted by the direct-current component adjustment unit 21. Thus, the comparison unit 23 includes the first comparator 23-1 and the second comparator 23-2.

An electric signal having a direct-current component adjusted by the direct-current component adjustment unit 21 is input to the non-inversion input (+) of the first comparator 23-1, and the upper threshold value is input to the inversion input (−). Whether a positive amplitude of the electric signal having the direct-current component adjusted by the direct-current component adjustment unit 21 exceeds the upper threshold value can be detected by the first comparator 23-1. Further, an electric signal having a direct-current component controlled by the direct-current component adjustment unit 21 is input to the inversion input (−) of the second comparator 23-2, and the lower threshold value is input to the non-inversion input (+). Whether a negative amplitude of the electric signal having the direct-current component adjusted by the direct-current component adjustment unit 21 falls below the lower threshold value can be detected by the second comparator 23-2.

A signal output from the comparison unit 23 (the first comparator 23-1 and the second comparator 23-2) is input to the wired OR connection unit 24. The wired OR connection unit 24 is provided for taking a logical sum (OR) of a signal output when it is determined by the first comparator 23-1 that a positive amplitude of an electric signal exceeds the upper threshold value and a signal output when it is determined by the second comparator 23-2 that a negative amplitude of an electric signal falls below the lower threshold value. With the wired OR connection unit 24, occurrence of noise can be detected even when either the case where it is determined by the first comparator 23-1 that a positive amplitude of an electric signal exceeds the upper threshold value and the case where it is determined by the second comparator 23-2 that a negative amplitude of an electric signal falls below the lower threshold value occurs first.

The comparison unit 23 and the wired OR connection unit 24 are formed of, for example, a reset IC.

The filter 25 and the buffer 26 have functions of suppressing fluctuations in occurrence or non-occurrence of noise that may occur as a result of generating a noise detection signal, based on comparison with a threshold value, and improving noise detection accuracy.

For example, with the configuration described above, when an electric signal generated in the lead wire 11 is determined to be greater than the upper threshold value or smaller than the lower threshold value, i.e., when an electric signal generated in the lead wire 11 falls outside the threshold value range between the upper threshold value and the lower threshold value, the noise detection circuit 12 generates and outputs a noise detection signal indicating occurrence of noise. Further, when an electric signal generated in the lead wire 11 is determined to be smaller than the upper threshold value and greater than the lower threshold value, i.e., when an electric signal generated in the lead wire 11 falls within the threshold value range between the upper threshold value and the lower threshold value, the noise detection circuit 12 generates and outputs a noise detection signal indicating non-occurrence of noise. For example, the noise detection signal indicates Low when occurrence of noise is indicated, and the noise detection signal indicates High when non-occurrence of noise is indicated. The noise detection signal generated in the noise detection circuit 12 as described above is input to the data processing circuit 13.

### Function of Noise Detection Circuit

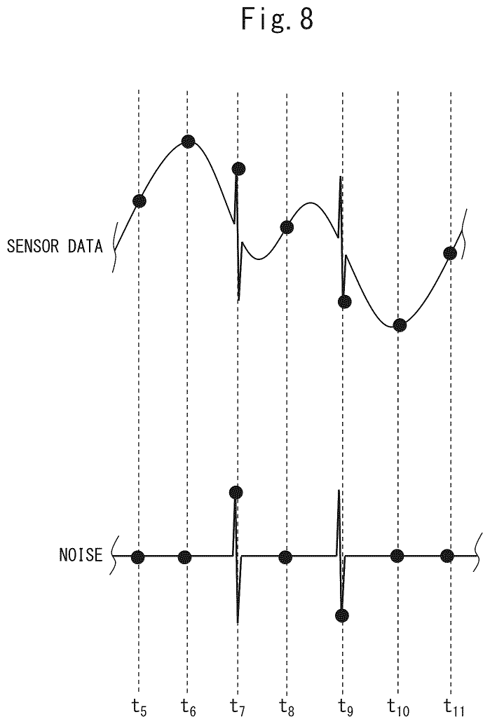

FIG. 8 is a waveform diagram illustrating a function of the noise detection circuit in the noise removal circuit according to the embodiment of the present disclosure. FIG. 8 illustrates, by a black dot, a sampling point by the data processing circuit 13 for the sensor data output from the sensor circuit 2 of the torque sensor 100. In other words, the data processing circuit 13 samples the sensor data output from the sensor circuit 2 at a time t₅, a time t₆, a time t₇, a time t₈, a time t₉, a time t₁₀, and a time t₁₁.

When the torque sensor 100 is present near the electric cable 200 through which the motor driving power flows, noise occurs in the sensor data output from the sensor circuit 2 of the torque sensor 100. In the example illustrated in FIG. 8, as one example, noise occurs at the time t₇ and the time t₉. If noise is to be directly detected by monitoring, as they are, the sensor data output from the sensor circuit 2, a size of the sensor data including noise at the time t₇ and the time t₉ falls between the sensor data (maximum value) at the time t₆ not including noise and the sensor data (minimum value) at the time t₁₀ not including noise. Thus, there is a possibility that the sensor data including noise and the normal sensor data not including noise cannot be accurately distinguished. In contrast, in the embodiment of the present disclosure, only noise is detected by the noise detection circuit 12, based on an electric signal generated in the lead wire 11 being wired in such a way as to surround the electric cable 200 (the lower waveform diagram in FIG. 8), and thus noise can be accurately detected.

### Relationship Between Noise Detection Signal and Invalidation Processing Period

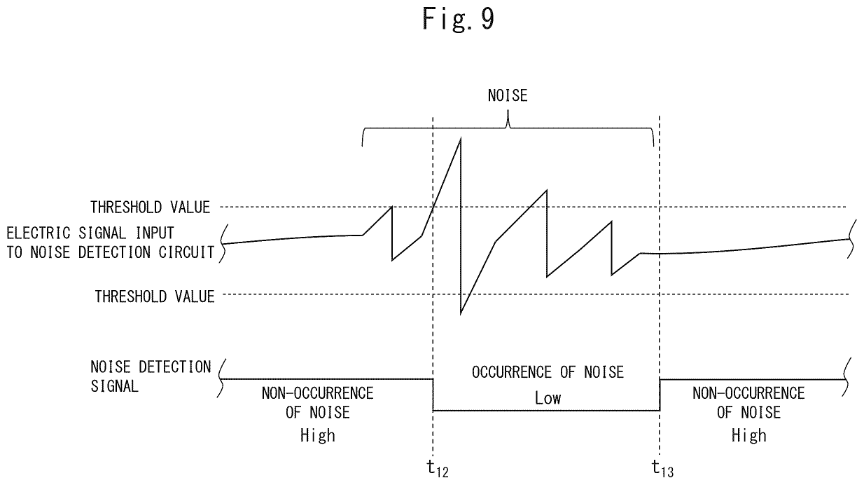

FIG. 9 is a waveform diagram illustrating a noise detection signal generated by the noise detection circuit in the noise removal circuit according to the embodiment of the present disclosure.

When an electric signal generated in the lead wire 11 (electric signal having a direct-current component adjusted by the direct-current component adjustment unit 21 in FIG. 7) falls outside a threshold value range, the noise detection circuit 12 generates a noise detection signal indicating occurrence of noise. In the example illustrated in FIG. 9, an electric signal input to the noise detection circuit 12 (i.e., an electric signal generated in the lead wire 11) exceeds an upper threshold value at a time t₁₂. Thus, the noise detection circuit 12 outputs a noise detection signal (Low) indicating occurrence of noise during a period from the time t₁₂ to a time t₁₃ after a lapse of a predetermined period, and the noise detection circuit 12 outputs a noise detection signal (High) indicating non-occurrence of noise during the other period. An arrangement of an inverter circuit and the electric cable 200 that have an electrical influence on the torque sensor 100 provided in the robot 1000 does not change greatly from a time of manufacturing of a robot, and thus noise included in an electric signal generated in the lead wire 11 has reproducibility. Thus, time required since noise occurs until the noise is suppressed is also fixed. Thus, in the embodiment of the present disclosure, time required since noise occurs until the noise is suppressed is measured in advance at a time of development of the robot 1000 and the like, and time required since noise occurs until the noise is suppressed is set based on the measured time. A constant of the filter 25 is determined based on the set time.

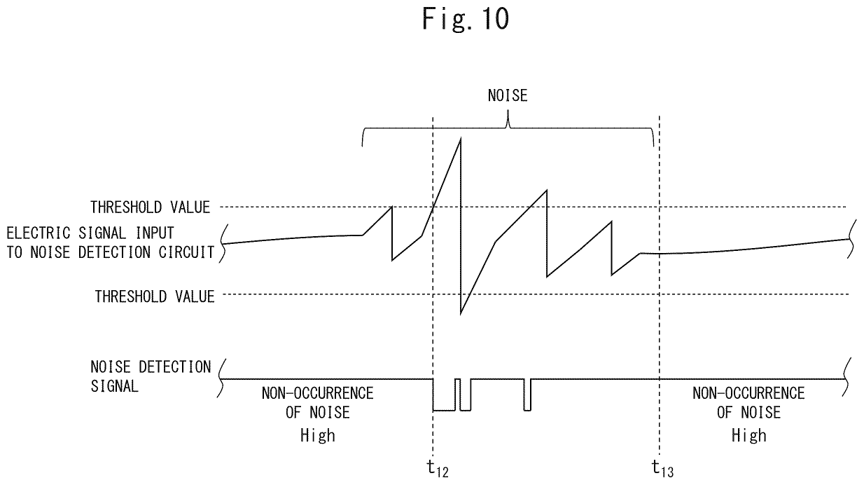

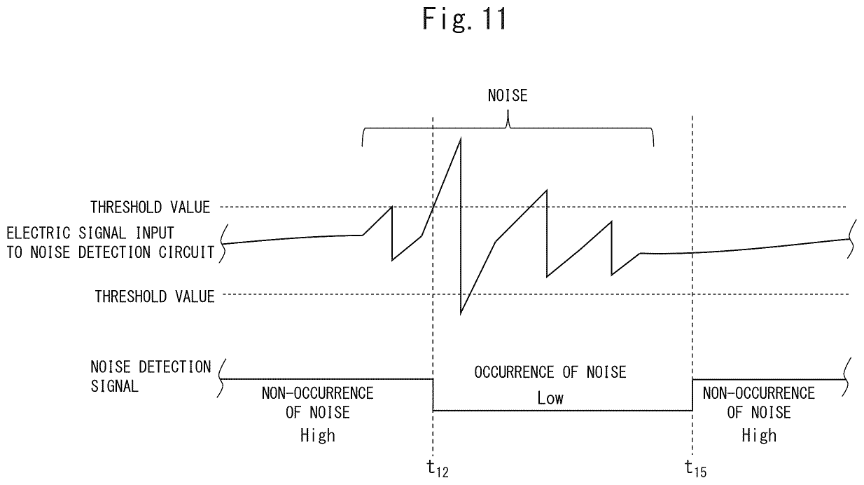

FIGS. 10 and 11 are waveform diagrams illustrating setting of the filter by the noise detection circuit in the noise removal circuit according to the embodiment of the present disclosure.

As illustrated in FIG. 10, when a constant of the filter 25 is set to be weak, a relationship in magnitude between the upper threshold value and the lower threshold value is reversed in a short time in an electric signal input to the noise detection circuit 12 (i.e., an electric signal generated in the lead wire 11). Thus, “fluctuations in a noise detection signal” in which switching between the noise detection signal (Low) indicating occurrence of noise and the noise detection signal (High) indicating non-occurrence of noise occurs in a short time occur.

As illustrated in FIG. 11, when a constant of the filter 25 is set to be strong, a period of time from the time t₁₂ at which an electric signal input to the noise detection circuit 12 (i.e., an electric signal generated in the lead wire 11) exceeds the upper threshold value and the noise detection signal (Low) indicating occurrence of noise is thus output to a time t₁₅ at which the noise detection signal (High) indicating non-occurrence of noise is output is long. As a result, even data being a portion without noise is invalidated more than necessary.

Thus, in the embodiment of the present disclosure, time required since noise occurs until the noise is suppressed is measured in advance at a time of development of the robot 1000 and the like, time required since noise occurs until the noise is suppressed is set based on the measured time, and an appropriate constant of the filter 25 is determined based on the set time.

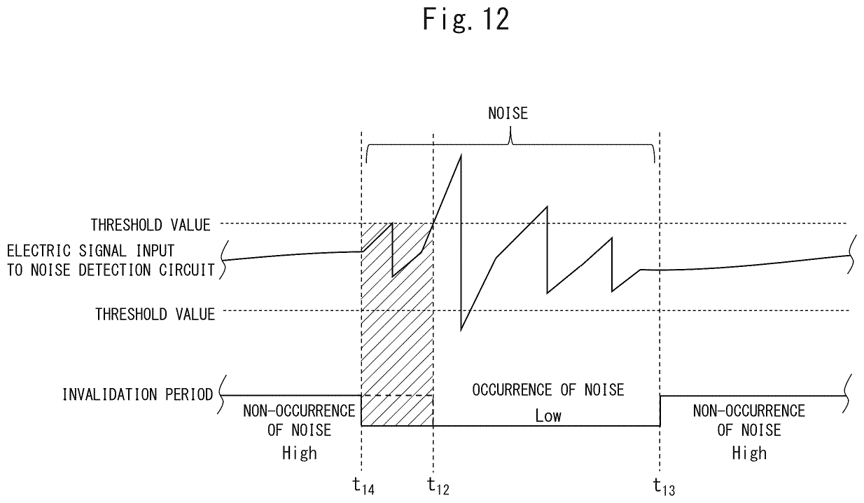

FIG. 12 is a waveform diagram illustrating a relationship between noise and data in an invalidation period in the embodiment of the present disclosure.

As described with reference to FIG. 9, the time t₁₂ being a point in time at which an electric signal generated in the lead wire 11 falls outside the threshold value range is a starting point of the noise detection signal (Low) indicating occurrence of noise. However, noise to the extent that a threshold value is not exceeded actually occurs since a point in time before the time t₁₂ being the starting point of the noise detection signal. As described above, noise included in the electric signal generated in the lead wire 11 has reproducibility. Thus, in the embodiment of the present disclosure, time required since noise occurs until the electric signal exceeds a threshold value is measured in advance at a time of development of the robot 1000 and the like, and a point in time before, by a predetermined period of time, the starting point of the noise detection signal (Low) indicating occurrence of noise is set as a starting point of an invalidation period of sensor data, based on the measured time. In the example illustrated in FIG. 12, a time t₁₄ before the time t₁₂ being the starting point of the noise detection signal (Low) indicating occurrence of noise is set as a starting point of the invalidation period of the sensor data. It should be noted that invalidation processing of the sensor data needs to be executed at the time t₁₄ before the time t₁₂ being the starting point of the noise detection signal (Low) indicating occurrence of noise. Thus, the sensor data output from the sensor circuit 2 are temporarily held in a storage unit (not illustrated) in the noise removal circuit 1, and the data processing circuit 13 executes, on the sensor data held in the storage unit, processing of invalidating the sensor data during the invalidation period.

It should be noted that, in order to more simplify the configuration and the processing in the noise removal circuit 1, the time t₁₂ being the starting point of the noise detection signal (Low) indicating occurrence of noise may be set as a starting point of the invalidation period of the sensor data. In this case, the sensor data do not need to be temporarily held, and thus the storage unit can be eliminated.

### Data Invalidation Processing by Data Processing Circuit

The data processing circuit 13 invalidates the sensor data during the invalidation period including at least a period in which the noise detection signal indicates occurrence of noise among the sensor data output from the sensor circuit 2. A few examples of the data invalidation processing by the data processing circuit will be listed below.

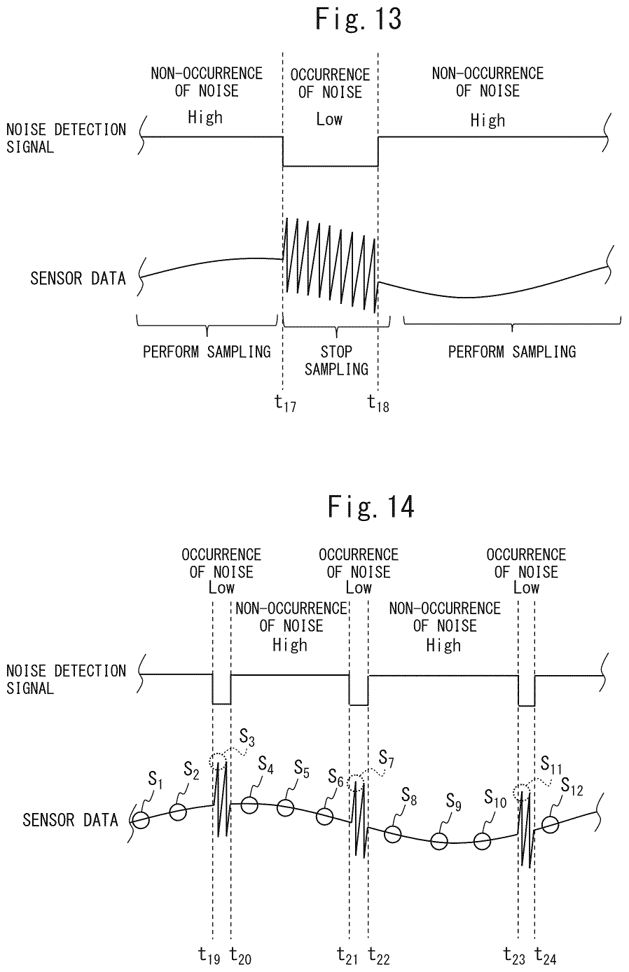

FIG. 13 is a waveform diagram illustrating the data invalidation processing in a first aspect of the data processing circuit in the noise removal circuit according to the embodiment of the present disclosure. In the example illustrated in FIG. 13, as one example, a starting point of the noise detection signal (Low) indicating occurrence of noise is set as a starting point of the invalidation period of the sensor data. it should be noted that, a point in time before, by a predetermined period of time, the starting point of the noise detection signal (Low) indicating occurrence of noise may be set as a starting point of the invalidation period of the sensor data in the data processing circuit 13.

In the data invalidation processing in the first aspect, the data processing circuit 13 outputs, as they are, data output from the sensor circuit 2 during a period other than the invalidation period, and stops an output of the data output from the sensor circuit 2 during the invalidation period. In the example illustrated in FIG. 13, the noise detection signal (Low) indicating occurrence of noise is output from the noise detection circuit 12 from a time t₁₇ to a time t₁₈, and thus an output of the data output from the sensor circuit 2 is stopped during the invalidation period from the time t₁₇ to the time t₁₈, and the data output from the sensor circuit 2 are output as they are during a period other than the invalidation period. The data invalidation processing in the first aspect can remove an influence of noise from the sensor data.

FIG. 14 is a waveform diagram illustrating the data invalidation processing in a second aspect of the data processing circuit in the noise removal circuit according to the embodiment of the present disclosure. FIG. 14 illustrates, as S₁ to S₁₂, sampling points by the data processing circuit 13 for the sensor data output from the sensor circuit 2. In the example illustrated in FIG. 14, as one example, a starting point of the noise detection signal (Low) indicating occurrence of noise is set as a starting point of the invalidation period of the sensor data. It should be noted that, a point in time before, by a predetermined period of time, the starting point of the noise detection signal (Low) indicating occurrence of noise may be set as a starting point of the invalidation period of the sensor data in the data processing circuit 13.

In the data invalidation processing in the second aspect, the data processing circuit 13 invalidates the sensor data during the invalidation period among the sensor data output from the sensor circuit 2, and then averages and outputs values indicated by the sensor data output from the sensor circuit 2 during a predetermined period including the invalidation period. In the example illustrated in FIG. 14, the sensor data in the sampling points S₃, S₇, and S₁₁ from a time t₁₉ to a time t₂₀, from a time t₂₁ to a time t₂₂, and from a time t₂₃ to a time t₂₃ are invalidated. Then, values indicated by the sensor data in the sampling points S₁, S₂, S₄, S₅, S₆, S₈, S₉, S₁₀ and S₁₂ during a period other than the invalidation period are averaged and output. Time and a period in which averaging is performed can be set freely. For example, when the sensor data output from the sensor circuit 2 are an analog signal, a value indicated by the sensor data may vary due to thermal noise, but the data invalidation processing in the second aspect can more reliably remove an influence of noise from the sensor data, and generate the sensor data with high accuracy about torque.

As described above, according to the embodiment of the present disclosure, the lead wire 11 is wired around the electric cable 200 being a source of occurrence of noise, noise is detected based on an electric signal generated in the lead wire 11, and a data portion influenced by noise among the sensor data output from the sensor circuit 2 is invalidated. With such a configuration, an abnormal value influenced by noise can be appropriately removed from the sensor data output from (the sensor circuit 2 of) the torque sensor 100, and thus the sensor data with high accuracy about torque can be generated.

Since motor driving power subjected to PWM control is generally quickly switched between High and Low, sensor data of a torque sensor located around an electric cable through which the motor driving power flows is more likely to be influenced by noise. For example, a measure of reducing an influence of noise by averaging time of sensor data has been conventionally taken, but there is a problem that a high speed of sensor processing is lost. In contrast, according to the embodiment of the present disclosure, a data portion influenced by noise among the sensor data output from the sensor circuit 2 is invalidated, and thus a high speed of sensor processing can be secured.

If noise is to be directly detected by monitoring, as they are, sensor data output from a sensor circuit, a size of the sensor data including noise falls between a maximum value of the sensor data not including noise and a minimum value of sensor data not including noise. Thus, there is a possibility that the sensor data including noise and the normal sensor data not including noise cannot be accurately distinguished. In contrast, in the embodiment of the present disclosure, only noise is detected by the noise detection circuit 12, based on an electric signal generated in the lead wire 11 being wired in such a way as to surround the electric cable 200, and thus noise can be accurately detected.

The printed circuit board of the torque sensor 100 provided in the arm of the robot may have an opening for passing various cables. The embodiment of the present disclosure has the configuration in which the lead wire 11 is wired in such a way as to surround the opening of the printed circuit board 3 of the torque sensor 100, and thus a noise removal circuit can also be easily mounted on a former torque sensor.

### Modification Example and Alternative Example of Embodiment

In the embodiment described above, it is assumed that the noise detection signal indicates Low when occurrence of noise is indicated, and the noise detection signal indicates High when non-occurrence of noise is indicated. As an alternative example, the noise detection signal may indicate High when occurrence of noise is indicated, and the noise detection signal may indicate Low when non-occurrence of noise is indicated.

In the embodiment described above, it is assumed that the electric cable 200 is a power cable through which motor driving power flows. As an alternative example, the electric cable 200 may be a cable other than a power cable through which motor driving power flows. For example, the electric cable 200 may be a signal cable through which a PWM signal used for controlling an inverter flows, or a power cable through which power supply power flows.

In the embodiment described above, it is assumed that the sensor circuit 2 is provided in the torque sensor 100 that detects torque of the target object 300. As a modification example, the sensor circuit 2 may be provided in a sensor other than a torque sensor. For example, the sensor circuit 2 may be a sensor circuit configured to output electrical sensor data among a current sensor, a voltage sensor, a magnetic sensor, a speed sensor, a temperature sensor, and the like.

Although the embodiments of the present disclosure have been described above in detail, the present disclosure is not limited to the individual embodiments described above. Various types of addition, replacement, modification, partial deletion, and the like may be made to the embodiments without departing from the purpose of the invention or without departing from the contents described in the claims and the scope of the present invention derived from equivalents thereof. For example, in the embodiments described above, an order of operations and an order of pieces of processing are indicated as one example, which is not limited thereto. Further, the same also applies to a case where a numerical value or a numerical expression is used in the description of the embodiments described above.

### REFERENCE SIGNS LIST

1 Noise removal circuit
2 Sensor circuit
3 Printed circuit board
11 Lead wire
12 Noise detection circuit
13 Data processing circuit
21 Direct-current component adjustment unit
21-1 Capacitor
21-2, 21-3 Resistor
22 Threshold value setting unit
23 Comparison unit
23-1 First comparator
23-2 Second comparator
24 Wired OR connection unit
25 Filter
26 Buffer
31 Opening
100 Torque sensor
200 Electric cable
300 Target object
1000 Robot

1. A noise removal circuit configured to remove an influence of noise from data output from a sensor circuit, the noise removal circuit comprising:
a lead wire being wired in such a way as to surround an electric cable;
a noise detection circuit configured to generate a noise detection signal indicating occurrence or non-occurrence of noise in the electric cable, based on an electric signal generated in the lead wire; and
a data processing circuit configured to invalidate data during an invalidation period including at least a period in which the noise detection signal indicates occurrence of noise among data output from the sensor circuit.

2. The noise removal circuit according to claim 1, wherein
the data processing circuit outputs, as they are, data output from the sensor circuit during a period other than the invalidation period, and stops an output of data output from the sensor circuit during the invalidation period.

3. The noise removal circuit according to claim 1, wherein
the data processing circuit invalidates data during the invalidation period among data output from the sensor circuit, and then averages and outputs values indicated by data output from the sensor circuit during a predetermined period including the invalidation period.

4. The noise removal circuit according to claim 1, wherein
a point in time before, by a predefined period of time, a period in which the noise detection signal indicates occurrence of noise is set as a starting point of the invalidation period.

5. The noise removal circuit according to claim 1, wherein
the noise detection circuit includes
a direct-current component adjustment unit configured to adjust a direct-current component from an electric signal generated in the lead wire, and
a noise detection signal generation unit configured to generate and output the noise detection signal indicating occurrence of noise when it is determined by the direct-current component adjustment unit that an amplitude of the electric signal having the direct-current component adjusted falls outside a predefined threshold value range.

6. A sensor comprising:
a sensor circuit configured to output data being a sensor detection result of a target object;
the noise removal circuit according to claim 1 configured to remove an influence of noise from data output from the sensor circuit; and
a printed circuit board having an opening through which the electric cable passes, and on which the lead wire is wired in such a way as to surround the opening.

7. The sensor according to claim 6, wherein
the sensor circuit and the noise removal circuit are provided on the printed circuit board.
